(19) United States
(12) Patent Application Publication
(10) Pub. No.: US 2022/0068749 A1
(43) Pub. Date: Mar. 3, 2022

(54) CIRCUIT ASSEMBLY WITH THERMAL COATING IN CONTACT WITH EXPOSED METAL EDGES

(71) Applicant: Innogrit Technologies Co., Ltd., Shanghai (CN)

(72) Inventors: Yanwen BAI, Shanghai (CN); Shiann-Ming LIOU, Campbell, CA (US)

(21) Appl. No.: 17/010,285

(22) Filed: Sep. 2, 2020

(30) Foreign Application Priority Data
Aug. 31, 2020 (CN) 202018994422.3

(51) Int. Cl. H01L 23/367; H01L 23/498; H01L 21/48

(52) U.S. Cl. CPC H01L 23/367; H01L 23/49822; H01L 23/3736; H01L 23/49805; H01L 21/4857

(57) ABSTRACT

Apparatus and methods are provided for providing thermal management for semiconductor packages or PCBs. In an exemplary embodiment, there is provided a circuit assembly that may comprise a plurality of metal layers each having exposed edges along peripheral sides of a respective metal layer and a thermal coating layer covering an outer surface of the circuit assembly. The thermal coating layer may be in direct contact with the exposed edges of each of the plurality of metal layers at the peripheral sides of the respective metal layer.

### TECHNICAL FIELD

The disclosure herein relates to thermal management for circuit assemblies, particularly relates to heat dissipation for semiconductor packages or printed circuit boards (PCBs).

### BACKGROUND

Modern computing devices, for example, computer servers for providing cloud-based services or portable devices such as smart phones, are all getting more powerful and faster. At the same time, more functionalities are provided and more storage space are needed. But there is a limit on available space and thus the functional electrical modules and storage devices have to be smaller and packed denser. High speed performance always causes thermal issues under limited device size. Therefore, for a lot of next generation devices, such as PCI Express (PCIe) 4 or PCIe 5 high speed card, heat dissipation problem needs to be faced and solved.

The industry has tried to resolve this issue by using high thermal conductivity molding compound or adding metal connector. These approaches, however, are high cost solutions. In addition to raising other issues, e.g., warpage, they require devices to be designed to follow new standard card form factor and have totally newly designed card connector. Moreover, heat dissipation efficiency in these solutions is not good enough to meet the thermal management requirement because the coefficient of thermal conductivity of molding compound cannot reach metals. Accordingly, there is a need in the art for more efficient thermal management.

### SUMMARY

A continuing need exists for improved thermal management for Integrated Circuit (IC) packages and PCBs. An IC package may also be referred to as a semiconductor package. The disclosed subject matter relates to apparatuses and methods that provide efficient heat dissipation in an IC package or a PCB by a low-cost approach. In various embodiment, multiple metal layers of an IC package or a PCB may have edges exposed at the peripheral and the IC package or PCB may have a thermal coating that makes contact with the edges of the metal layers. Accordingly, heat generated inside the IC package and PCB may be conducted out by the metal layers to the thermal coating and dissipated by the thermal coating. Moreover, in some embodiments, the thermal coating may be in touch with external metal components, such as card connectors and other thermal management components, such as heat pipe, heat sink, etc. Therefore, heat dissipation may be greatly improved in various embodiments.

One exemplary embodiment according to the present disclosure may provide a circuit assembly that may comprise a plurality of metal layers each having exposed edges along peripheral sides of a respective metal layer and a thermal coating layer covering an outer surface of the circuit assembly. The thermal coating layer may be in direct contact with the exposed edges of each of the plurality of metal layers at the peripheral sides of the respective metal layer.

In yet another exemplary embodiment, there is provide a method for making a circuit assembly. The method may comprise forming a partial circuit assembly with a plurality of metal layers that each has exposed edges along peripheral sides of a respective metal layer and forming a thermal coating layer covering an outer surface of the partial circuit assembly. The thermal coating layer may be in direct contact with the exposed edges of each of the plurality of metal layers at the peripheral sides of the respective metal layer.

### BRIEF DESCRIPTION OF FIGURES

FIG. 1A schematically shows a cross-sectional view of a circuit assembly in accordance with an embodiment of the present disclosure.

FIG. 1B schematically shows a cross-sectional view of a partial circuit assembly in accordance with an embodiment of the present disclosure.

FIG. 1C schematically shows a cross-sectional view of a substrate strip having a plurality of partial circuit assemblies in accordance with an embodiment of the present disclosure.

FIG. 1D schematically shows a top view of the substrate strip of FIG. 1C in accordance with an embodiment of the present disclosure.

FIG. 2A schematically shows a top view of a metal layer in accordance with an embodiment of the present disclosure.

FIG. 2B schematically shows a top view of a metal layer in accordance with another embodiment of the present disclosure.

FIG. 3 is a flowchart of a process for making a circuit assembly in accordance with an embodiment of the present disclosure.

### DETAILED DESCRIPTION

Specific embodiments according to the present disclosure will now be described in detail with reference to the accompanying figures. Like elements in the various figures are denoted by like reference numerals for consistency.

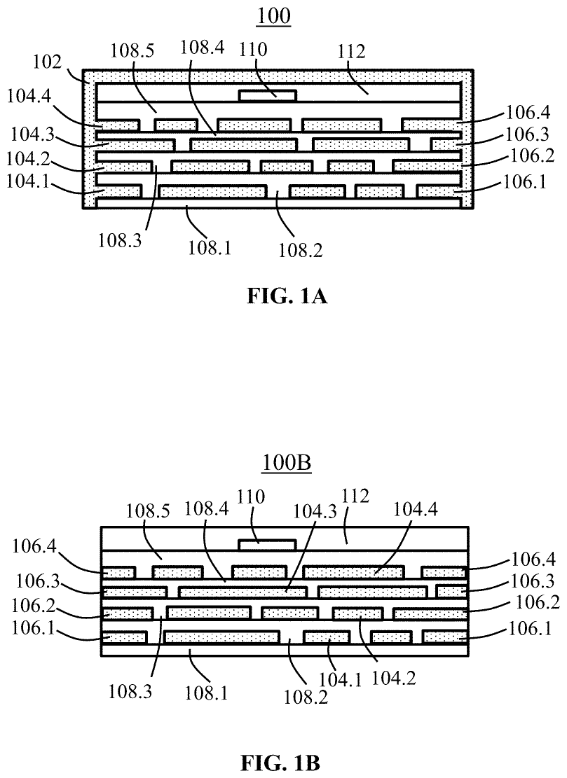

FIG. 1A schematically shows a cross-sectional view of a circuit assembly 100 in accordance with an embodiment of the present disclosure. The circuit assembly 100 may comprise a thermal coating 102, a plurality of metal layers 104.1, 104.2, 104.3 and 104.4, a semiconductor component 110 and a layer 112 of molding compound. The outer surface of the thermal coating 102 may be the outer surface of the circuit assembly 100. The thermal coating 102 may be a layer of material with a high thermal conductivity, for example, metal, such as, but not limited to, copper. The thermal coating 102 may have direct contact with the plurality of metal layers 104.1, 104.2, 104.3 and 104.4 at their peripheral edges 106.1, 106.2, 106.3 and 106.4. It should be noted that the exposed edges 106.1, 106.2, 106.3 and 106.4 may be at the peripheral sides (e.g., left, right, front and back) of the plurality of metal layers 104.1, 104.2, 104.3 and 104.4, not just by the right side. In some embodiments, the thermal coating 102 may cover an outer surface of the circuit assembly that may include all sides of the circuit assembly 100 with the exception of the bottom side.

Each of the plurality of metal layers 104.1, 104.2, 104.3 and 104.4 may be separated from any adjacent metal layer by a dielectric layer. For example, the metal layer 104.1 may be on top of a dielectric layer 108.1 and covered by another dielectric layer 108.2, the metal layer 104.2 may be on top of the dielectric layer 108.2 and covered by another dielectric layer 108.3, the metal layer 104.3 may be on top of the dielectric layer 108.3 and covered by another dielectric layer 108.4, and the metal layer 104.4 may be on top of the dielectric layer 108.4 and covered by another dielectric layer 108.5.

In one embodiment, a dielectric layer underneath may serve as a substrate for a metal layer on top. For example, the dielectric layer 108.1 may serve as a substrate for the metal layer 104.1. Each of the dielectric layers (e.g., any of dielectric layer 108.1 through 108.5) may be filled with one or more non-conductive dielectric material, such as, but not limited to, a prepreg material. The dielectric layers may be made of same material or different materials.

In some embodiments, the circuit assembly 100 may be a semiconductor package (also known as an IC package), and the plurality of metal layers 104.1 through 104.4 and the dielectric layers 108.1 through 108.5 may be part of a package substrate, and there may be one or more semiconductor dies attached to the top of the top dielectric layer (e.g., the dielectric layer 108.5). In an embodiment that the circuit assembly 100 may be a semiconductor package, there may be one or more semiconductor dies (with one semiconductor component 110 shown as an example) attached on top of the dielectric layer 108.5 and covered by the molding compound layer 112. In some other embodiments, the circuit assembly 100 may be a printed circuit board (PCB), and the plurality of metal layers 104.1 through 104.4 and the dielectric layers 108.1 through 108.5 may be part of PCB layers and there may be one or more semiconductor chips attached to the top of the top dielectric layer (e.g., the dielectric layer 108.5). In an embodiment that the circuit assembly 100 may be a PCB, there may be one or more semiconductor chips (with one semiconductor component 110 shown as an example) attached on top of the dielectric layer 108.5 and covered by the molding compound layer 112.

It should be noted that an embodiment of the circuit assembly 100 may have other layers in some embodiments. For example, there may be one or more dielectric layers and one or more metal layers on top of the dielectric layer 108.5, one or more dielectric layers and one or more metal layers underneath the dielectric layer 108.1, or one or more dielectric layers and one or more metal layers between any adjacent metal layer and dielectric layer. In some embodiments, any dielectric layer (e.g., the dielectric layers 108.1 through 108.5) may include two or more layers of different dielectric materials.

In general, there may be N metal layers in an embodiment of the circuit assembly with N greater than one. The circuit assembly 100 shows an embodiment with the plurality of metal layers 104.1, 104.2, 104.3 and 104.4 in which N may be 4. It should be noted that in some embodiments, an embodiment of the multi-layer circuit assembly 100 may have a total number of layers more than the total number of metal layers that have exposed edges.

FIG. 1B schematically shows a cross-sectional view of a partial circuit assembly 100B in accordance with an embodiment of the present disclosure. The partial circuit assembly 100B may be an embodiment of a partially completed circuit assembly 100 before the thermal coating layer 102 is applied. As shown in FIG. 1B, the peripheral edges 106.1, 106.2, 106.3 and 106.4 are also on the left of the plurality of metal layers. In some embodiments, the thermal coating layer 102 may be applied to cover the top and four sides (e.g., front, left, back and right) of the partial circuit assembly 100B but not the bottom.

For embodiments that the circuit assembly 100 may be a PCB, each partial circuit assembly 100B may be formed individually. For embodiments that the circuit assembly 100 may be a semiconductor package, a plurality of partial circuit assemblies 100B may be formed together on a substrate strip. FIG. 1C schematically shows a cross-sectional view of a substrate strip 114 in accordance with an embodiment of the present disclosure. The substrate strip 114 may comprise a plurality of partial circuit assemblies 100B. In one embodiment, the substrate strip 114 may be cut in a singulation process along the saw street 116. The dotted line 118 shows a cut surface through the metal layers and metal edges of two adjacent partial circuit assemblies exposed on the cut surface. The singulation process may be any known or future developed techniques, such as, but not limited to, a mechanical process using saw or a non-mechanical process using laser. As shown in FIG. 1C, although not labeled, the plurality of metal edges 106.1, 106.2, 106.3 and 106.4 may be exposed on the cut surface. FIG. 1D schematically shows a top view of the substrate strip 114 in accordance with an embodiment of the present disclosure. As shown in FIG. 1D, the substrate strip 114 may be a panel comprising a plurality of partial circuit assemblies 100B in a matrix form. Individual partial circuit assemblies 100B may be obtained by cutting the substrate strip 114 in a singulation process along the saw streets 116.

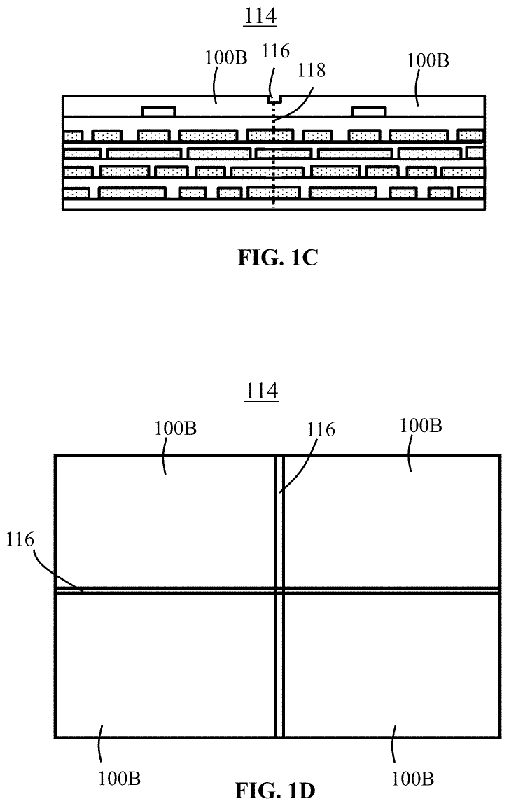

FIG. 2A schematically shows a top view of a metal layer 200A in accordance with an embodiment of the present disclosure. The metal layer 200A may be an embodiment for any of the plurality of metal layers 104.1 through 104.4 in the circuit assembly 100. The metal layer 200A may comprise an inner region 202A and a peripheral region 204. It should be noted that there is no actual physical distinction between the two regions or any physical line separating the two regions. The peripheral region 204 may surround the inner region 202A. The inner region 202A may have openings in the metal material of the metal layer 200A. These openings may comprise electrical components, such as, but not limited to, vias, signal traces, power traces, etc. The openings and any electrical components inside the openings that are not ground reference may be insulated from the metal material of the metal layer 200A.

The peripheral region 204 may comprise a plurality of openings and protrusions around the metal layer 200A on four sides (e.g., left, top, right and bottom). For simplicity, only the openings 208.1, 208.2, 208.3, 208.4 and 208.5 and protrusions 206.1, 206.2, 206.3 and 206.4 along the left side of the metal layer 200A may be labeled. The protrusions may have edges exposed (e.g., the edges 106.1 through 106.4 in FIG. 1) and ready to make contact with a thermal coating layer. A protrusion along the peripheral of the metal layer 200A may expose an edge of width “W” and an opening along the peripheral of the metal layer 200A may leave a gap of width “D.” In some embodiments, the sum of widths of all edges of protrusions may be larger than the sum of all widths of all gaps. That is, the sum of widths of all exposed edges may be larger than 50% of the total length of the perimeter of the metal layer 200A. In an embodiment, the metal layer 200A may be a ground plane or a VSS plane in a multi-layer semiconductor substrate or a multi-layer PCB.

FIG. 2B schematically shows a top view of a metal layer 200B in accordance with another embodiment of the present disclosure. The metal layer 200B may also be an embodiment for any of the plurality of metal layers 104.1 through 104.4 in the circuit assembly 100. The metal layer 200B may comprise an inner region 202B and a peripheral region 204. It should be noted that there is no actual physical distinction between the two regions or any physical line separating the two regions. The peripheral region 204 may surround the inner region 202B. The inner region 202B may comprise one or more regions 210 which may have openings in the metal material of the metal layer 200B. These openings may be insulated from the metal material of the metal layer 200B and may comprise electrical components, such as, but not limited to, vias, signal traces, power traces, etc. The one or more regions 210 may be part of a signal plane or a power plane (e.g., a VDD plane).

The peripheral region 204 may comprise a plurality of openings and protrusions around the metal layer 200A on four sides (e.g., left, top, right and bottom). For simplicity, only the openings 208.1, 208.2, 208.3, 208.4 and 208.5 and protrusions 206.1, 206.2, 206.3 and 206.4 along the left side of the metal layer 200B may be labeled. The protrusions may have edges exposed and ready to make contact with a thermal coating layer. A protrusion along the peripheral of the metal layer 200B may expose an edge of width “W” and an opening along the peripheral of the metal layer 200B may leave a gap of width “D.” In some embodiments, the sum of widths of all edges of protrusions may be larger than the sum of all widths of all gaps. That is, the sum of widths of all exposed edges may be larger than 50% of the total length of the perimeter of the metal layer 200B. In an embodiment, the metal layer 200B may comprise ground traces or VSS traces in a signal layer plane or a power plane.

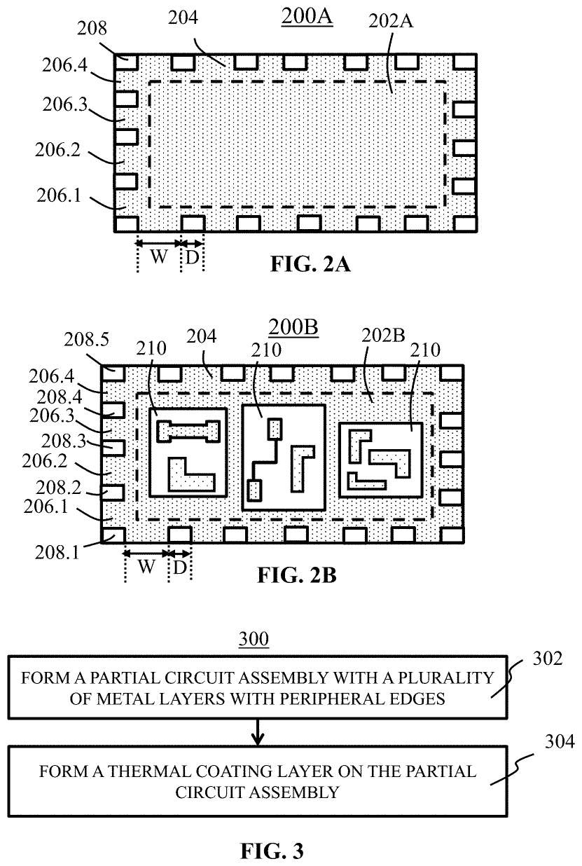

FIG. 3 is a flowchart of a process 300 for making a circuit assembly in accordance with an embodiment of the present disclosure. The process 300 may be followed to make an embodiment of the circuit assembly 100. At block 302, a partial circuit assembly with a plurality of metal layers may be formed. The plurality of metal layers may have exposed peripheral edges. For example, an embodiment of the partial circuit assembly 100B may be formed and the embodiment of the partial circuit assembly 100B may comprise the plurality of metal layers 104.1 through 104.4. In an embodiment, each of the metal layers 104.1 through 104.4 may be formed by a process to making conductive pattern on a substrate, for example, an additive process, a semi-additive process or a subtractive process. In some embodiments, after the plurality of metal layers may be formed, one or more semiconductor components may be attached to a top dielectric layer of the partial circuit assembly and a molding process may be applied to cover the semiconductor components with a layer of molding compound.

In embodiments that the circuit assembly 100 may be a PCB, an embodiment of the partial circuit assembly 100B may be formed individually. For example, after the metal layers 104.1 through 104.4 may be formed, a semiconductor chip (e.g., semiconductor component 110) may be attached and bonded. A molding compound layer may be formed at the top of the partial circuit assembly 100B to cover the semiconductor chip.

For embodiments that the circuit assembly 100 may be a semiconductor package, a plurality of partial circuit assemblies 100B may be formed together on a substrate strip and one partial circuit assembly 100B may be cut from the substrate strip with peripheral edges exposed even after a singulation process. In some embodiments, the substrate strip with a plurality of partial circuit assemblies may be formed with the plurality of metal layers 104.1 through 104.4 formed as repeated patterns each corresponding to a partial circuit assembly. Then one or more semiconductor dies may be attached for each of the partial circuit assembly. A molding compound layer may cover the top of the substrate strip to cover the semiconductor dies. The substrate strip may be cut to obtain an individual partial circuit assembly.

At block 304, a thermal coating layer may be formed. For example, the thermal coating layer 102 in the circuit assembly 100 may be formed by a sputter or another suitable process to cover the outer surface of the partial circuit assembly 100B with the exception of the bottom. In some embodiments, the thermal coating layer 102 may have a thickness of several micrometers and may be a metal material, such as, but not limited to, copper or silver. The exposed edges along the periphery of each of the plurality of metal layers (e.g., the metal layers 104.1 through 104.4) may be in direct contact with the thermal coating layer such that the plurality of metal layers may have direct contact with the thermal coating layer to dissipate heat through the thermal coating layer.

Embodiments according to present disclosure may provide thermal management for high speed devices, such as IC packages or PCBs so that the high speed devices may continue providing ultra high performance during operation. For example, in an embodiment, the circuit assembly 100 may be a PCI Express (PCIe) 4 or PCIe 5 card. Moreover, in some embodiments, the circuit assembly 100 may comprise external components, such as card connectors, and/or other thermal management components, such as heat pipe, heat sink, fan, etc. The thermal coating layer in these embodiments may be in direct contact with external components to provide further improved heat dissipation. Therefore, heat dissipation may be greatly improved in various embodiments. Thermal coating and special package design may improve heat dissipation performance with high efficiency.

One exemplary embodiment according to the present disclosure may provide a circuit assembly that may comprise a plurality of metal layers each having exposed edges along peripheral sides of a respective metal layer and a thermal coating layer covering an outer surface of the circuit assembly. The thermal coating layer may be in direct contact with the exposed edges of each of the plurality of metal layers at the peripheral sides of the respective metal layer.

In one embodiment, a sum of widths of all exposed edges for each of the plurality of metal layers may be larger than 50% of a total length of a perimeter of the respective metal layer.

In one embodiment, two adjacent metal layers of the plurality of metal layers may be separated by at least one non-conductive dielectric layer.

In one embodiment, the circuit assembly may further comprise an external component in direct contact with the thermal coating layer. The external component may be configured for further improved heat dissipation.

In one embodiment, each of the plurality of metal layers may be generated on top of a respective dielectric layer by an additive process, a semi-additive process or a subtractive process.

In one embodiment, the thermal coating layer is applied by a sputter process.

In one embodiment, at least one of the plurality of metal layers may comprise one or more ground traces or VSS traces on a signal layer.

In one embodiment, at least one of the plurality of metal layers may be a ground layer.

In one embodiment, the circuit assembly may further comprise a semiconductor die and the plurality of metal layers may be part of a package substrate for the semiconductor die.

In one embodiment, the circuit assembly may further comprise a semiconductor chip and the plurality of metal layers may be part of a printed circuit board on which the semiconductor chip is attached.

In yet another exemplary embodiment, there is provide a method for making a circuit assembly. The method may comprise forming a partial circuit assembly with a plurality of metal layers that each has exposed edges along peripheral sides of a respective metal layer and forming a thermal coating layer covering an outer surface of the partial circuit assembly. The thermal coating layer may be in direct contact with the exposed edges of each of the plurality of metal layers at the peripheral sides of the respective metal layer.

In one embodiment, a sum of widths of all exposed edges for each of the plurality of metal layers may be larger than 50% of a total length of a perimeter of the respective metal layer.

In one embodiment, two adjacent metal layers of the plurality of metal layers may be separated by at least one non-conductive dielectric layer.

In one embodiment, the at least one non-conductive dielectric layer may be made of a prepreg material.

In one embodiment, each of the plurality of metal layers may be generated on top of a respective dielectric layer by an additive process, a semi-additive process or a subtractive process.

In one embodiment, the thermal coating layer may be applied by a sputter process.

In one embodiment, at least one of the plurality of metal layers may comprise one or more ground traces or VSS traces on a signal layer.

In one embodiment, at least one of the plurality of metal layers may be a ground layer.

In one embodiment, the circuit assembly may be a semiconductor package and forming the partial circuit assembly may further comprise: forming a substrate strip with a plurality of partial circuit assemblies and cutting the partial circuit assembly from the substrate strip. Forming the substrate with a plurality of partial circuit assemblies may further include: forming the plurality of metal layers on the substrate strip; attaching semiconductor dies to the plurality of metal layers for each the plurality of partial circuit assemblies to have at least one semiconductor die; and covering the semiconductor dies with a molding compound layer.

In one embodiment, the circuit assembly may be a printed circuit board and forming the partial circuit assembly may further comprise attaching a semiconductor chip to the plurality of metal layers and covering the semiconductor chip with a molding compound layer.

Various operations may be described as multiple discrete operations in turn, in a manner that may be helpful in understanding embodiments of the present invention; however, the order of description should not be construed to imply that these operations are order dependent. Moreover, some embodiments may include more or fewer operations than may be described.

The description may use the phrases “in an embodiment,” “in embodiments,” “in some embodiments,” or “in various embodiments,” which may each refer to one or more of the same or different embodiments. Furthermore, the terms “comprising,” “including,” “having,” and the like, as used with respect to embodiments of the present invention, are synonymous.

The terms chip, die, integrated circuit, monolithic device, semiconductor device, and microelectronic device are often used interchangeably in the microelectronics field. The present invention is applicable to all of the above as they are generally understood in the field.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A circuit assembly, comprising:
a plurality of metal layers each having exposed edges along peripheral sides of a respective metal layer; and
a thermal coating layer covering an outer surface of the circuit assembly, wherein the thermal coating layer is in direct contact with the exposed edges of each of the plurality of metal layers at the peripheral sides of the respective metal layer.

2. The circuit assembly of claim 1, wherein a sum of widths of all exposed edges for each of the plurality of metal layers is larger than 50% of a total length of a perimeter of the respective metal layer.

3. The circuit assembly of claim 1, wherein two adjacent metal layers of the plurality of metal layers are separated by at least one non-conductive dielectric layer.

4. The circuit assembly of claim 1, further comprising an external component in direct contact with the thermal coating layer, wherein the external component is configured for further improved heat dissipation.

5. The circuit assembly of claim 1, wherein each of the plurality of metal layers is generated on top of a respective dielectric layer by an additive process, a semi-additive process or a subtractive process.

6. The circuit assembly of claim 1, wherein the thermal coating layer is applied by a sputter process.

7. The circuit assembly of claim 1, wherein at least one of the plurality of metal layers comprises one or more ground traces or VSS traces on a signal layer.

8. The circuit assembly of claim 1, wherein at least one of the plurality of metal layers is a ground layer.

9. The circuit assembly of claim 1, further comprising a semiconductor die, wherein the plurality of metal layers are part of a package substrate for the semiconductor die.

10. The circuit assembly of claim 1, further comprising a semiconductor chip, wherein the plurality of metal layers are part of a printed circuit board on which the semiconductor chip is attached.

11. A method of making a circuit assembly, comprising:
forming a partial circuit assembly with a plurality of metal layers that each has exposed edges along peripheral sides of a respective metal layer; and
forming a thermal coating layer covering an outer surface of the partial circuit assembly, wherein the thermal coating layer is in direct contact with the exposed edges of each of the plurality of metal layers at the peripheral sides of the respective metal layer.

12. The method of claim 11, wherein a sum of widths of all exposed edges for each of the plurality of metal layers is larger than 50% of a total length of a perimeter of the respective metal layer.

13. The method of claim 11, wherein two adjacent metal layers of the plurality of metal layers are separated by at least one non-conductive dielectric layer.

14. The method of claim 13, wherein the at least one non-conductive dielectric layer is made of a prepreg material.

15. The method of claim 11, wherein each of the plurality of metal layers is generated on top of a respective dielectric layer by an additive process, a semi-additive process or a subtractive process.

16. The method of claim 11, wherein the thermal coating layer is applied by a sputter process.

17. The method of claim 11, wherein at least one of the plurality of metal layers comprises one or more ground traces or VSS traces on a signal layer.

18. The method of claim 11, wherein at least one of the plurality of metal layers is a ground layer.

19. The method of claim 11, wherein the circuit assembly is a semiconductor package and forming the partial circuit assembly further comprises:
forming a substrate strip with a plurality of partial circuit assemblies, including:
forming the plurality of metal layers on the substrate strip;
attaching semiconductor dies to the plurality of metal layers, each of the plurality of partial circuit assemblies having at least one semiconductor die; and
covering the semiconductor dies with a molding compound layer; and
and cutting the partial circuit assembly from the substrate strip.

20. The method of claim 11, wherein the circuit assembly is a printed circuit board and forming the partial circuit assembly further comprises attaching a semiconductor chip to the plurality of metal layers and covering the semiconductor chip with a molding compound layer.
